(19) United States
(12) Patent Application Publication
(10) Pub. No.: US 2024/0087776 A1
(43) Pub. Date: Mar. 14, 2024

(54) CURRENT SHUNT WITH CANCELING MUTUAL INDUCTANCE

(71) Applicant: Tektronix, Inc., Beaverton, OR (US)

(72) Inventors: Julie A. Campbell, Beaverton, OR (US); Christopher R. Muggli, Hillsboro, OR (US); Daniel G. Knierim, Beaverton, OR (US); David M. Ediger, Portland, OR (US); Richard N. Atherton, Aloha, OR (US)

(73) Assignee: Tektronix, Inc., Beaverton, OR (US)

(21) Appl. No.: 18/243,632

(22) Filed: Sep. 7, 2023

Related U.S. Application Data
(60) Provisional application No. 63/405,837, filed on Sep. 12, 2022.

(51) Int. Cl. H01C 7/00; G01R 1/067

(52) U.S. Cl. CPC H01C 7/00; G01R 1/067

(57) ABSTRACT

A shunt resistor has a substrate having electrically conductive structures to carry current in a current path, a resistive portion in electrical contact with the electrically conductive structures, and one or more canceling inductance leads electrically connected to the electrically conductive structures and the resistive portion, the one or more canceling inductance configured to cancel inductive effects in a voltage measurement across the resistive portion. A modular tip interconnect has a connector at a first end of the interconnect configured to connect to a probe tip of a test and measurement instrument, and the above shunt resistor located at a second end of the interconnect configured to connect to a device under test (DUT).

### CROSS-REFERENCE TO RELATED APPLICATIONS

This disclosure claims benefit of U.S. Provisional Application No. 63/405,837, titled “CURRENT SHUNT WITH CANCELING MUTUAL INDUCTANCE,” filed on Sep. 12, 2022, the disclosure of which is incorporated herein by reference in its entirety.

### TECHNICAL FIELD

This disclosure relates to test and measurement systems, and more particularly to a system for measuring electrical current in a device under test (DUT).

### BACKGROUND

U.S. Pat. App. Pub. No. 20210318361A1, published Oct. 14, 2021, the contents of which are hereby incorporated by reference into this disclosure in their entirety, describes an isolated differential current shunt probe for measuring electrical current in a device under test (DUT). The shunt uses the voltage drop across a shunt resistor, as well as techniques for minimizing the inductance of the current shunt. Similarly, U.S. patent application Ser. No. 18/198,800, filed May 17, 2023, and U.S. patent application Ser. No. 18/225,034, filed Jul. 21, 2023, both incorporated by reference here in their entirety, describe different approaches to current shunts for use in test and measurement instruments.

Developing and testing switching power supplies, motor drives, battery chargers, wireless chargers, photo-voltaic inverters, and other related power electronics typically involves current measurements. One common approach to measuring current involves placing a low-value resistor, often referred to as a “current shunt,” or “shunt resistor” in series with a path of the current to be measured. Measuring the resultant voltage drop across the current shunt allows determination of the electrical current based on the known resistance of the current shunt.

One approach often used is to place a series resistor (or “shunt”) in the current path, measure the voltage drop caused by the current, and divide by the resistance. This approach handles DC and lower frequencies well, but suffers at higher frequencies due to the inductive drop across the shunt, which exceeds the resistive drop for frequencies above a frequency f_{c}:

$$V = R \cdot i + L \cdot \frac{di}{dt} {f}_{c} = \frac{R}{2 π \cdot L}$$

When measuring large currents, a relatively small shunt resistance R is needed to keep the voltage drop and power dissipation of the shunt within reason, which leads to objectionably low usable bandwidth f_{c}.

Another method to improve the usable bandwidth of a shunt is to add a canceling mutual inductance, M_{c}, in the lead dress of the voltage measurement leads of a conventional shunt:

$$V = R \cdot i + L \cdot \frac{di}{dt} - {M}_{C} \cdot \frac{di}{dt}$$

This minimizes the insertion inductance by not requiring a particular return current path. It is trickier to implement because the return current path must still be known to determine lead placement to achieve cancelation (M_{c}=L). The cancellation approach also suffers at high frequency due to skin effect. The current path through the shunt will shift in physical location as the skin depth approaches the shunt thickness, changing the values of M_{c}, L, and R, in the above equation.

Examples of the disclosure address these and other deficiencies of the prior art.

### BRIEF DESCRIPTION OF THE DRAWINGS

FIG. 1 shows a diagram of an embodiment of a shunt resistor with current and measurement paths.

FIGS. 2-5 show embodiments of a substrate having a shunt resistor and inductance-canceling leads.

FIG. 6 shows an alternative embodiment of a shunt resistor with inductance-canceling leads.

FIGS. 7-8 show an embodiment of a shunt resistor with via connections.

FIGS. 9-11 show different views of an embodiment of a shunt having vias.

FIG. 12 shows an embodiment of tip extensions with an interconnect.

FIG. 13 shows an embodiment of an interconnect for a square pin connector.

FIG. 14 shows an embodiment of an interconnect with a flex circuit substrate.

FIG. 15 shows an embodiment of an interconnect to a device under test.

### DETAILED DESCRIPTION

Embodiments of this disclosure include implementations of current shunt structures, including details around cancelling mutual inductance, interconnect, and the management of Kelvin sensing. As mentioned above, one method to improve the usable bandwidth of a shunt is to add a canceling mutual inductance, M_{c}, in the lead dress of the voltage measurement leads of a conventional shunt:

$$V = R \cdot i + L \cdot \frac{di}{dt} - {M}_{C} \cdot \frac{di}{dt} .$$

This minimizes the insertion inductance by not requiring a particular return current path but is trickier to implement because the return current path must still be known to determine lead placement to achieve cancelation (M_{c}=L). The cancelation approach also suffers at high frequency due to skin effect. The current path through the shunt will shift in physical location as the skin depth approaches the shunt thickness, changing the values of M_{c}, L, and R.

Embodiments of this disclosure leverage a Kelvin sensing configuration of the resistor voltage drop. There is no current of the signal under test flowing through the canceling inductance measurement pick-off. For high-current applications, contact resistance may create a substantial gain error in the intended current measurement, which is where Kelvin sensing becomes important.

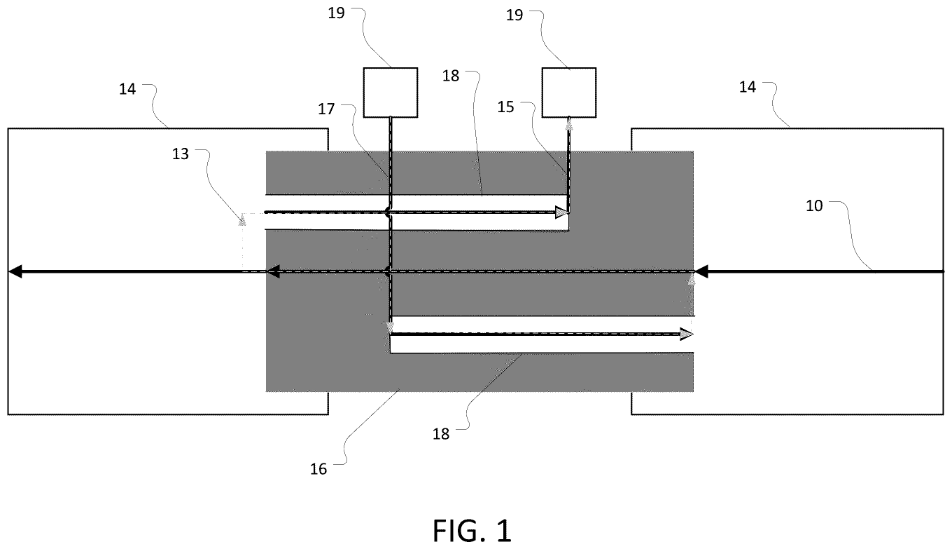

FIG. 1 shows a diagram of a shunt resistor and the associated current and measurement paths in accordance with the embodiments. The structure of the shunt resistor generally comprises a resistive material 16 between two electrically conductive structures 14. The current path follows arrow 10, and the voltage drop across the resistive material 16 allows for measurement of the current. The measurement paths are shown as the thicker black arrows 15 and 17, between the canceling inductance leads 18 and the contacts 19. The path 13 of the thinner dashed gray line, shows the E·d1 path from one contact 19 down to the lower lead 18, up through the resistive material along the current path, through the other lead 18 up to the other contact 19. The term E·d1 refers to the electric potential:

$$Δ V = - {\int }_{a}^{b} \vec{E} \cdot d \vec{l} .$$

The portion of the E·d1 path in the resistive material area picks up both the desired I·R voltage drop of the resistor, and the undesired L·di/dt inductive peaking term from the magnetic field looping the current path 10. However, the E·d1 path also picks up a canceling mutual inductance term M·di/dt from the portions of the path in the two leads 18. These are also looped by the magnetic field. The remaining portions of the E·d1 path, down the sides of the substrate and the traces on the printed circuit board or flex circuit, are perpendicular to the current flow. Because of that, these portions do not pick up any further magnetic coupling from the current flow. The below discussion sets out various embodiments of a shunt resistor having canceling inductance measurement leads, which the discussion may refer to more simply as measurement leads.

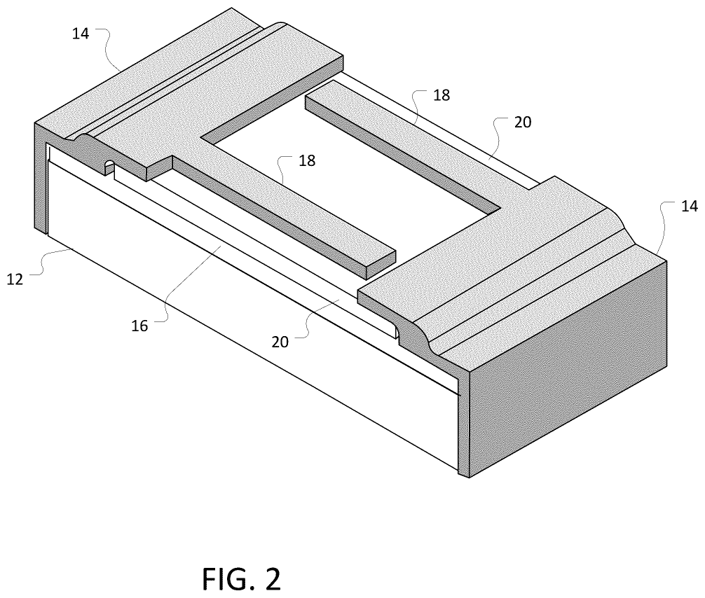

FIG. 2 shows an embodiment of a shunt resistor, or “shunt.” This embodiment comprises a co-fabricated ceramic substrate with a resistor and cancelling inductance measurement leads. In the below discussion, the term “resides” means that one part resides upon and is in contact with the part upon which it rests. Further, the different embodiments below may show the substrate and the components having different orientations, such as facing upwards relative to the page, or downwards. The embodiments do not limit the orientation of any embodiment to any specific orientation.

In the embodiment of FIG. 2, the shunt takes the form of a substrate having features of the shunt resistor painted or printed on it. In this embodiment, the substrate may comprise ceramic or other material co-fabricated with the resistor and inductance-canceling leads. Substrate 12 provides a surface or surfaces upon which the elements of the shunt resistor reside. In the embodiment of FIG. 2 the electrically conductive structures 14 comprise end caps. The electrically conductive structures contact either side of the resistive portion 16. The sense leads 18 allow for measurement of the voltage drop across the resistive portion 16. This embodiment of the shunt resistor includes an insulator 20 between the sense leads 18 and the resistive portion 16. One of the advantages here is the precise placement of the cancelling inductance enabling very high bandwidth (BW) precise measurements.

In one embodiment, the features are painted and/or printed on multiple sides to leverage the precise and micro geometry of a ceramic substrate. In one of the embodiments, a pen may allow the painting of the 3-D circuitry. Exxelia Micropen is an example of a manufacturer that can paint circuitry on 3-D shapes. There are frequency optimizations and measurement accuracies gained by leveraging the accuracy of ceramic substrates and circuit placement technologies. This approach may apply to any or all of the embodiments.

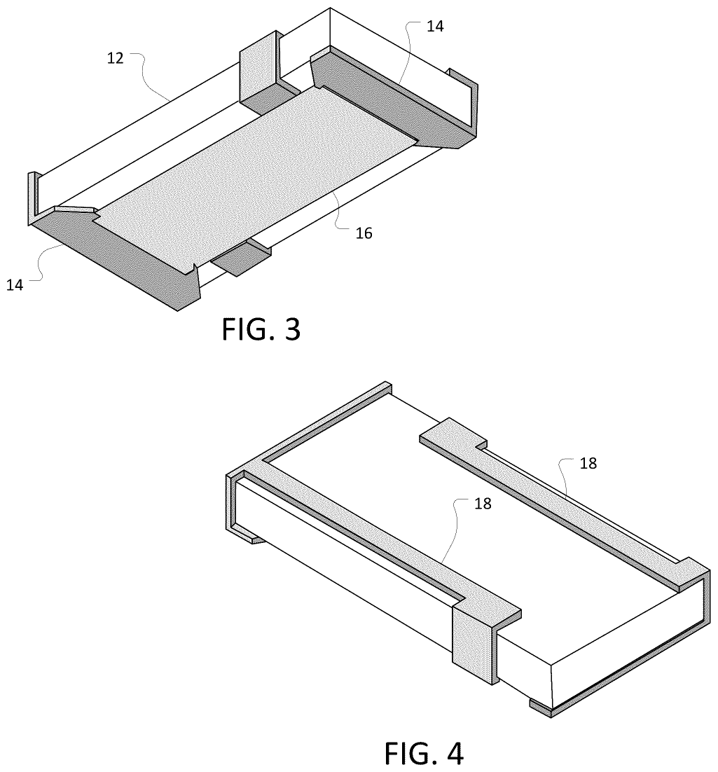

FIGS. 3 and 4 show another embodiment of a shunt construction, according to some embodiments of the disclosure. In FIG. 3, the resistive portion 16 resides on one surface of the substrate 12, and the leads 18 are on a second surface that is opposite the first surface as shown in FIG. 4. This embodiment does not use an insulator other than the substrate itself.

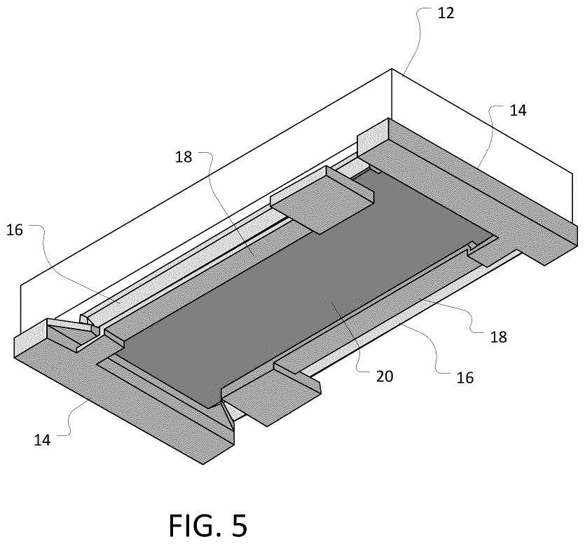

In FIG. 5, the electrically conductive structures 14, resistive portion 16 and the leads 18 all reside on one surface of the substrate 12. The electrically conductive structures 14 reside on the surface of the substrate 12 at opposing ends. Leads 18 extend from each of the connections onto the resistive portion 16. This embodiment uses an insulator 20 between the resistive portion 16 and the leads 18.

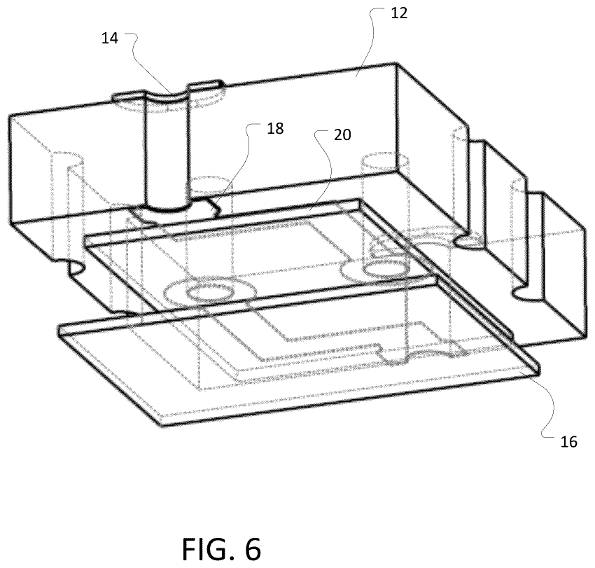

FIG. 6 shows the shunt resistor having a different ordering of the components. In this embodiment, the leads 18 reside on substrate 12. The substrate has electrically conductive structures 14 in the form of a via that may traverse from one side of the substrate to the other. The insulator 20 then resides on the leads 18, with the resistive portion 16 being the outermost layer of the shunt. This embodiment may lend itself well to surface mounting the resistor onto a test board or other circuit board, with the connections though the vias to allow for contact with the leads on the “top” or upper side of the substrate.

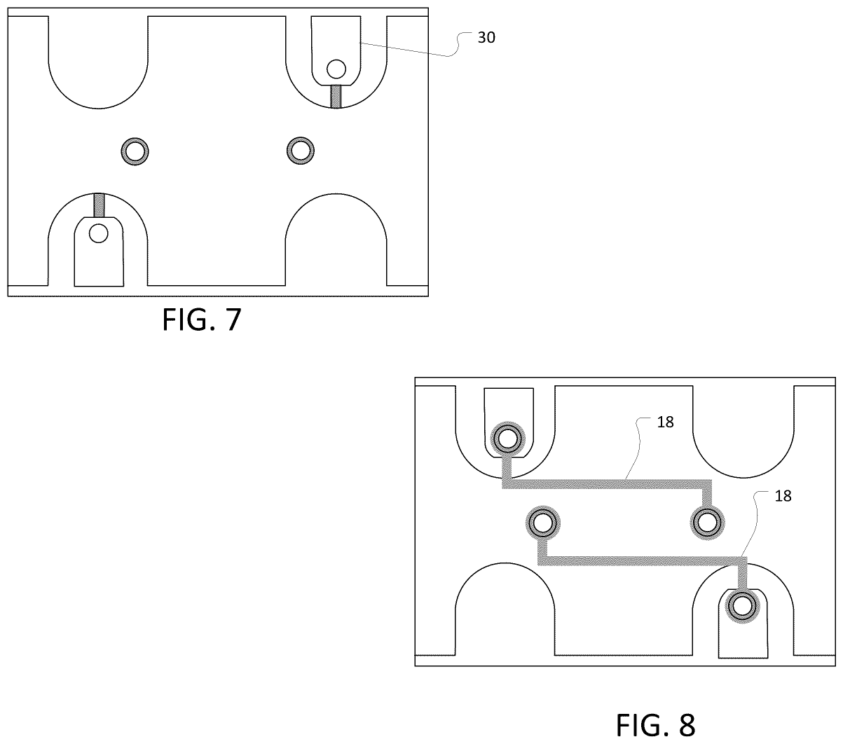

FIGS. 7 and 8 show an alternative substrate comprised of a thin film. FIG. 7 shows one side of the film with solder pads such as 30. The other side of the film, shown in FIG. 8 shows the leads 18. This embodiment leverages squeegee print techniques and vias to traverse the substrate and enable precise placement of the canceling inductance leads.

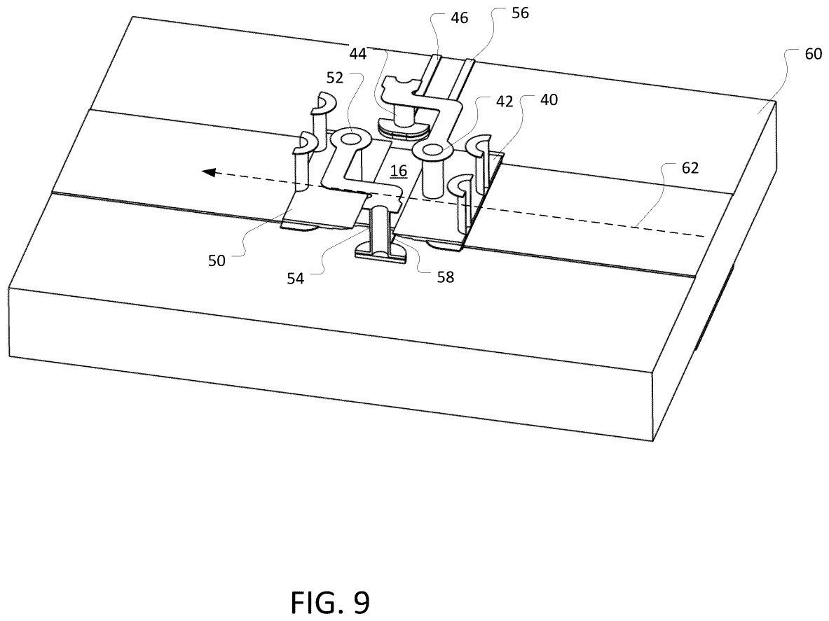

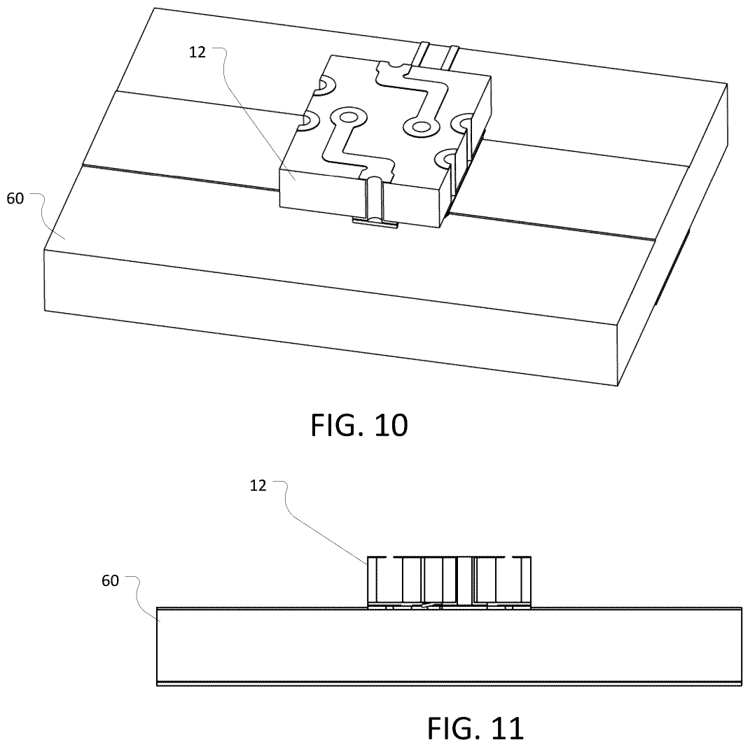

The use of vias has advantages in the routing of the sense leads. FIGS. 9-11 show another embodiment of the substrate having vias. FIG. 9 shows castellated vias and allows for viewing of the paths between the sense leads and the resistive portion. In FIG. 9, a first conductive path travels from the pad 40 that resides on the resistive portion 16, through the via up to the trace 42 that traverses over to the via 44 that contacts the first sense lead 46. The second conductive path travels from pad 50 in contact with the other side of the resistive portion 16 up through the via 52 over to the via 54 that is in contact with end portion 58 of the other sense lead 56. Note that the term “travels” is not meant to imply any kind of flow or direction. No current may flow in these first and second conductive paths in this structure, as the parameter being sensed is voltage. Current flow on the DUT 60 is shown in the direction of arrow 62, i.e. between pads 40 and 50 through resistive portion 16. FIGS. 10 and 11 show alternative views of this configuration, with FIG. 10 showing the vias as part of the substrate 12, on DUT 60, and FIG. 11 showing a side view.

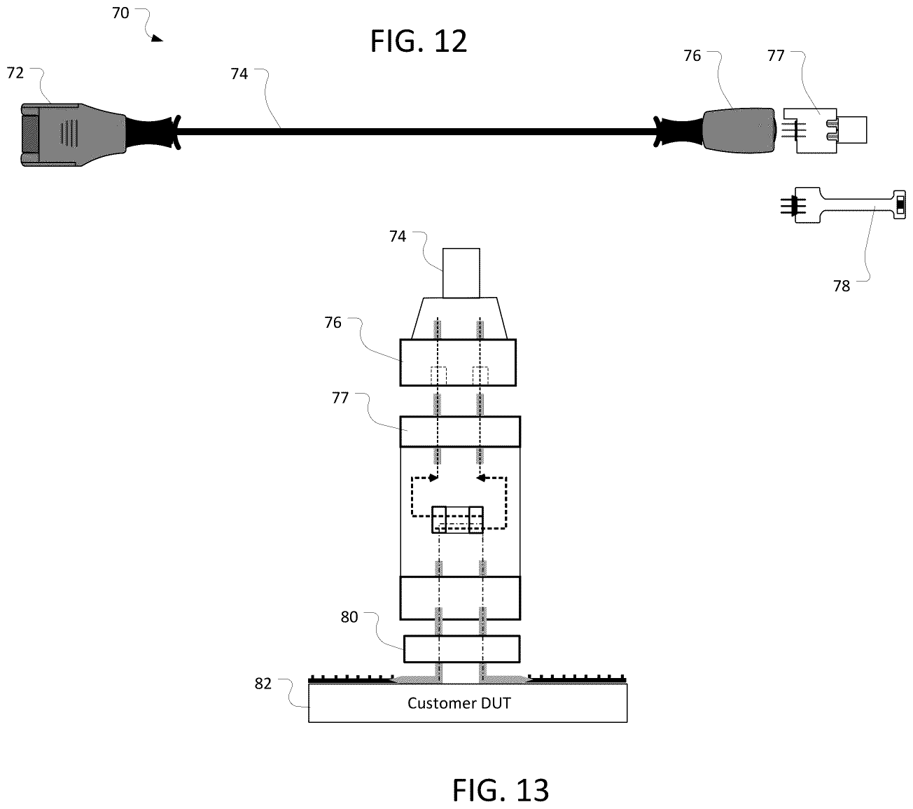

Measurement counter inductance, or canceling inductance, Kelvin sense shunt resistors of the embodiments may be integrated in the many different contact schemes. One embodiment integrates the shunt resistors with probe tip extensions. FIG. 12 shows an embodiment of a probe tip extension integrating the shunt resistor. The probe tip extension 70 has a probe connector 72, a transmission path 74, typically a cable of some kind, and a probe tip 76 that either includes the shunt resistor or connects to a connection that has the shunt resistor such as 77 or 78.

In some embodiments, the probe tip extensions have shunt identification signals to signal back to a connected oscilloscope to add tailored math and adjust display of the various measurement characteristics. The transmission path 74 can be twin ax, differential pair, or flex circuit differential pair, as examples, but may comprise many others.

The modular tip interconnect at the shunt resistor end of the tip extensions can have multiple configurations according to various embodiments. FIG. 13 shows a plug-in connector, sometimes referred to as a “chicklet” to connect to square-pins. The tip end 76 would plug into an intermediate structure, the plug-in connector such as 77, from FIG. 12. This then would connect to an adaptor or connector 80, that is mounted to the customer DUT 82. One should note that the term “customer DUT” includes directly mounted to the DUT itself or to a test board or circuit upon which the DUT resides.

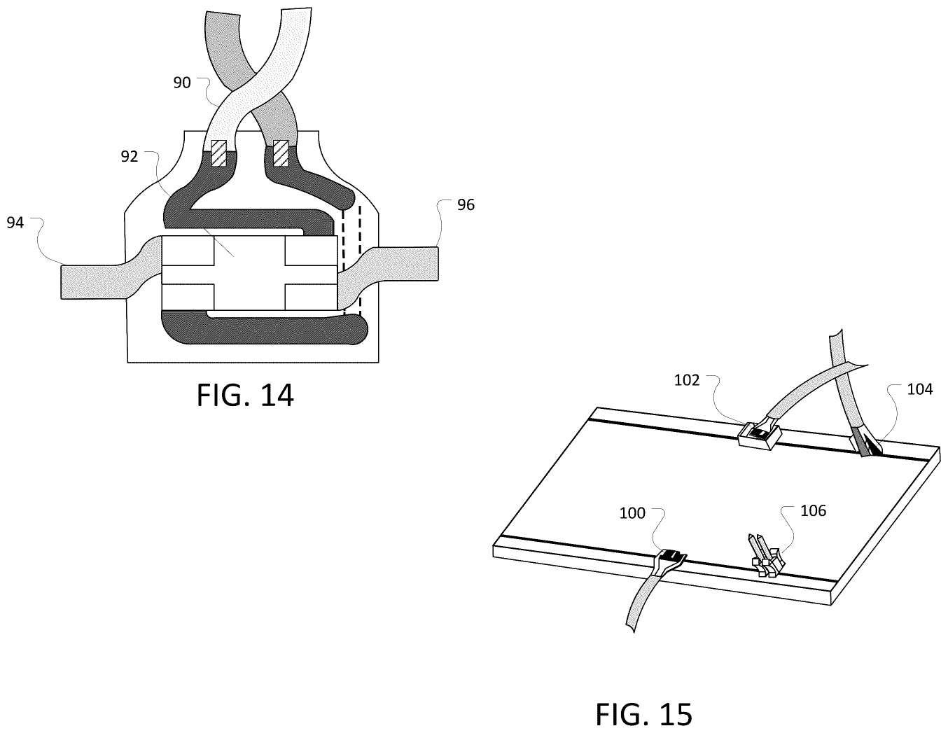

The modular tip interconnect could comprise wires or sculped flex to help manage measurement inductance using inductance canceling on a Kelvin-sensed shunt resistor. Returning to FIG. 12, the interconnect 78 could comprise a flex PCB upon which the sense leads land, as shown in FIG. 14. In this example, the transmission path 74 from FIG. 12 comprises a twisted pair connection 90. The connection to the shunt resistor 92 may comprise wire holes of sculpted flex circuits 94 and 96.

Further as shown in FIG. 15, the DUT interconnect could take many forms. As shown at 100, the resistor could be soldered directly to the DUT, by soldering in the tip. The resistor can connect using a clip as shown at 102 or a Browser at 104. The resistor could be mounted to a provided PCB and the PCB would mate to the device through a square pin header at 106.

In this way, a shunt resistor provides a means to allow measurement of a voltage drop across a resistor without having a negative impact on the accuracy of the measurement. In addition, the configurations above provide for canceling mutual inductance in the measurement path to provide a more accurate measurement.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

### EXAMPLES

Illustrative examples of the disclosed technologies are provided below. An embodiment of the technologies may include one or more, and any combination of, the examples described below.

Example 1 is a shunt resistor, comprising: a substrate having electrically conductive structures to carry current in a current path; a resistive portion in electrical contact with the electrically conductive structures; and one or more canceling inductance leads electrically connected to the electrically conductive structures and the resistive portion, the one or more canceling inductance leads configured to cancel inductive effects in a voltage measurement across the resistive portion.

Example 2 is the shunt resistor of Example 1, wherein: the electrically conductive structures comprise caps on opposite ends of the substrate; the resistive portion resides on and is in contact with the substrate; an insulator resides on and is in contact with the resistive portion; and the one or more canceling inductance leads reside on and are in contact with the insulator, each lead extending from one of the caps on opposite ends of the substrate.

Example 3 is the shunt resistor of either of Examples 1 or 2, wherein: the resistive portion resides on a first surface of the substrate opposite a second surface of the substrate; an insulator on a second surface of the substrate; and the one or more canceling inductance leads resides on the second surface of the substrate electrically connected to the electrically conductive structures.

Example 4 is the shunt resistor of any of Examples 1 through 3, wherein: the electrically conductive structures comprising pads on either end of a surface of the substrate; the resistive portion resides on and is in contact with the substrate between the electrically conductive structures; an insulator resides on and is in contact with the resistive portion; and the one or more canceling inductance leads extend from the pads and reside on and are in contact with the insulator.

Example 5 is the shunt resistor of any of Examples 1 through 4, wherein: the electrically conductive structures reside on a first surface of the substrate; the one or more canceling inductance leads is electrically connected to the electrically conductive structures on a first surface of the substrate; an insulator resides on the one or more canceling inductance leads; and the resistive portion resides on and is in contact with the insulator.

Example 6 is the shunt resistor of any of Examples 1 through 5, wherein the electrically conductive structures comprise vias traversing from a first surface of the substrate to a second surface of the substrate.

Example 7 is the shunt resistor of any of Examples 1 through 6, wherein the electrically conductive structures comprise castellated vias.

Example 8 is the shunt resistor of any of Examples 1 through 7, wherein the substrate comprises an insulating film, with the resistive portion residing on one surface of the film and the leads residing on a second surface of the film opposite the first surface.

Example 9 is the shunt resistor of any of Examples 1 through 8, wherein at least one of the resistive portion, the electrically conductive structures, and the leads, are one of painted or printed onto the substrate.

Example 10 is a modular tip interconnect, comprising: a connector at a first end of the interconnect configured to connect to a probe of a test and measurement instrument; and a shunt resistor located at a second end of the interconnect configured to connect to a device under test (DUT), the shunt resistor comprising: a substrate having electrically conductive structures to carry current in a current path; a resistive portion in electrical contact with the electrically conductive structures; and one or more canceling inductance leads electrically connected to the electrically conductive structures and the resistive portion, the one or more canceling inductance leads configured to cancel inductive effects in a voltage measurement across the resistive portion.

Example 11 is the modular tip interconnect of Example 10, further comprising a cable between the connector and the shunt resistor.

Example 12 is the modular tip interconnect of Example 11, wherein the cable comprises one of a differential cable, a coaxial cable, or a twisted pair cable.

Example 13 is the modular tip interconnect of any of Examples 10 through 12, wherein the shunt resistor resides in an intermediate structure between the cable and the DUT.

Example 14 is the modular tip interconnect of any of Examples 10 through 13, wherein the shunt resistor connects to an interconnect on the DUT.

Example 15 is the modular tip interconnect of Example 14, wherein the interconnect to the DUT comprises one of wires or a sculpted flexible circuit.

Example 16 is the modular tip interconnect of Example 15, wherein the leads land on the flex circuit.

Example 17 is the modular tip interconnect of Examples 10 through 16, wherein the shunt resistor is soldered directly to the DUT.

Although specific examples of the invention have been illustrated and described for purposes of illustration, it will be understood that various modifications may be made without departing from the spirit and scope of the invention. Accordingly, the invention should not be limited except as by the appended claims.

1. A shunt resistor, comprising:
a substrate having electrically conductive structures to carry current in a current path;
a resistive portion in electrical contact with the electrically conductive structures; and
one or more canceling inductance leads electrically connected to the electrically conductive structures and the resistive portion, the one or more canceling inductance leads configured to cancel inductive effects in a voltage measurement across the resistive portion.

2. The shunt resistor as claimed in claim 1, wherein:
the electrically conductive structures comprise caps on opposite ends of the substrate;
the resistive portion resides on and is in contact with the substrate;
an insulator resides on and is in contact with the resistive portion; and
the one or more canceling inductance leads reside on and are in contact with the insulator, each lead extending from one of the caps on opposite ends of the substrate.

3. The shunt resistor as claimed in claim 1, wherein:
the resistive portion resides on a first surface of the substrate opposite a second surface of the substrate;
an insulator on a second surface of the substrate; and
the one or more canceling inductance leads resides on the second surface of the substrate electrically connected to the electrically conductive structures.

4. The shunt resistor as claimed in claim 1, wherein:
the electrically conductive structures comprising pads on either end of a surface of the substrate;
the resistive portion resides on and is in contact with the substrate between the electrically conductive structures;
an insulator resides on and is in contact with the resistive portion; and
the one or more canceling inductance leads extend from the pads and reside on and are in contact with the insulator.

5. The shunt resistor as claimed in claim 1, wherein:
the electrically conductive structures reside on a first surface of the substrate;
the one or more canceling inductance leads is electrically connected to the electrically conductive structures on a first surface of the substrate;
an insulator resides on the one or more canceling inductance leads; and
the resistive portion resides on and is in contact with the insulator.

6. The shunt resistor as claimed in claim 1, wherein the electrically conductive structures comprise vias traversing from a first surface of the substrate to a second surface of the substrate.

7. The shunt resistor as claimed in claim 1, wherein the electrically conductive structures comprise castellated vias.

8. The shunt resistor as claimed in claim 1, wherein the substrate comprises an insulating film, with the resistive portion residing on one surface of the film and the leads residing on a second surface of the film opposite the first surface.

9. The shunt resistor as claimed in claim 1, wherein at least one of the resistive portion, the electrically conductive structures, and the leads, are one of painted or printed onto the substrate.

10. A modular tip interconnect, comprising:
a connector at a first end of the interconnect configured to connect to a probe of a test and measurement instrument; and
a shunt resistor located at a second end of the interconnect configured to connect to a device under test (DUT), the shunt resistor comprising:
a substrate having electrically conductive structures to carry current in a current path;
a resistive portion in electrical contact with the electrically conductive structures; and
one or more canceling inductance leads electrically connected to the electrically conductive structures and the resistive portion, the one or more canceling inductance leads configured to cancel inductive effects in a voltage measurement across the resistive portion.

11. The modular tip interconnect as claimed in claim 10, further comprising a cable between the connector and the shunt resistor.

12. The modular tip interconnect as claimed in claim 11, wherein the cable comprises one of a differential cable, a coaxial cable, or a twisted pair cable.

13. The modular tip interconnect as claimed in claim 10, wherein the shunt resistor resides in an intermediate structure between the cable and the DUT.

14. The modular tip interconnect as claimed in claim 10, wherein the shunt resistor connects to an interconnect on the DUT.

15. The modular tip interconnect as claimed in claim 14, wherein the interconnect to the DUT comprises one of wires or a sculpted flexible circuit.

16. The modular tip interconnect as claimed in claim 15, wherein the leads land on the flex circuit.

17. The modular tip interconnect as claimed in claim 10, wherein the shunt resistor is soldered directly to the DUT.
